(19) United States
(12) Patent Application Publication
(10) Pub. No.: US 2025/0079367 A1
(43) Pub. Date: Mar. 6, 2025

(54) METHOD FOR PRODUCING A SUBSTRATE HAVING A NANOPOROUS BUMP AND CORRESPONDING COMPONENT HAVING A SUBSTRATE WITH NANOPOROUS BUMP

(71) Applicant: Fraunhofer-Gesellschaft zur Förderung der angewandten Forschung e.V., München (DE)

(72) Inventors: Hans-Hermann Oppermann, Berlin (DE); Morten Brink, München (DE); Juliane Fröhlich, Berlin (DE)

(21) Appl. No.: 18/816,703

(22) Filed: Aug. 27, 2024

(30) Foreign Application Priority Data
Aug. 29, 2023 (DE) 10 2023 208 275.6

(51) Int. Cl. H01L 23/00

(52) U.S. Cl. CPC H01L 24/11; H01L 24/13; H01L 2224/11003; H01L 2224/11334; H01L 2224/11462; H01L 2224/13144

(57) ABSTRACT

A method for producing a substrate having a nanoporous bump may comprise providing a first substrate and a second substrate. The second substrate having a connection metallization. The method may further include electrodepositing a metal alloy by applying a voltage and de-alloying the metal alloy to produce a nanoporous bump. The method may further include compression bonding the nanoporous bump to the second substrate. A bump top side facing away from the first substrate is welded to the connection metallization of the second substrate. After the compression bonding, the second substrate is separated from the first substrate and the nanoporous bump is at least partially transferred from the first substrate to the second substrate.

### CLAIM FOR PRIORITY

This application claims the benefit of priority of German Application No. 10 2023 208 275.6, filed Aug. 29, 2023, which is hereby incorporated by reference in its entirety.

### TECHNICAL FIELD

The present disclosure relates to a method for producing a substrate having a nanoporous bump. Furthermore, the present disclosure may relate to a component, in particular a semiconductor component, having a corresponding substrate with nanoporous bump.

### BACKGROUND

In semiconductor technology, a chemical de-alloying process can be used to produce nanoporous bumps on a substrate, such as wafer substrates. Such a chemical de-alloying process may damage the substrate material or a material placed on the substrate.

### SUMMARY

Different systems (sputtering, lithography, electroplating) must be available depending on the wafer size. This leads to the problem of increased costs and reduced system flexibility with different wafer sizes.

Another problem may arise from the fact that some semiconductors are only available as chips and are unable to be supplied as wafers. This applies in particular to multi-project wafers, in which several customers share the wafer, each with their own circuits, and the wafer is separated after the manufacturing process and the chips are sent to the respective customers. The sensitive semiconductor materials that could be damaged by the de-alloying process include, for example, II/VI semiconductors such as detectors made of CdTe and CdZnTe or III/V semiconductors such as LEDs, laser diodes or high-frequency amplifiers made of InP, GaAs or GaN.

The present disclosure can help address at least one of the above-mentioned problems, in particular to propose a method that enables nanoporous bumps to be produced on sensitive substrates or on individual chips. The present disclosure may also help provide a corresponding substrate with nanoporous bumps, which comprises a material that is sensitive to the chemical de-alloying process.

At least one of these tasks is solved by a method having the features of the main claim or by a component comprising a corresponding substrate having the features of the coordinated claim.

Advantageous developments and improvements are possible by means of the measures specified in the dependent claims.

The proposed method for producing a substrate having a nanoporous bump can comprise the following steps:
providing a first substrate and a second substrate, wherein the second substrate has a connection metallization,
electrodepositing a metal alloy by applying a voltage,
de-alloying the metal alloy to produce a nanoporous bump,
compression bonding the nanoporous bump to the second substrate, wherein a bump top side facing away from the first substrate is welded to the connection metallization of the second substrate,
   characterized in that after compression bonding, the second substrate is separated from the first substrate, wherein the nanoporous bump is at least partially transferred from the first substrate to the second substrate.

The method may further comprise the following steps:
applying a plating base, for example comprising TiW/Au, to the first substrate,
applying a coating, in particular a photosensitive coating, to the plating base, for example by spinning,
exposing with a bump mask and developing the coating,

These steps may be carried out in particular before the electrodeposition. After the electrodeposition, the coating may be removed again. The plating base may be applied by sputtering or vapor deposition, for example.

Instead of applying a plating base to a substrate, a metal substrate with a starter layer, e.g., made of gold, may also be used. In addition or as an alternative to applying a photosensitive coating, it is possible to structure the coating mask using a hard mask by laser ablation or by dry etching.

As an alternative to exposing with a bump mask, the structure may also be written into the coating without a mask using a focused laser and exposed at the same time.

The proposed method has the advantage that method steps that place high demands on a substrate may be carried out with a first substrate, while the bump may subsequently be transferred to a second substrate, which may comprise more sensitive materials. The bump may also be transferred to a second substrate which, due to its format, is not suitable for the direct production of the bump on it, for example in the case of single chips. In the step of de-alloying the metal alloy to create the nanoporous bump, an etching solution is typically used for de-alloying. Many materials are unsuitable for exposure to such an etching solution as they would be damaged, for example organic materials such as printed circuit boards, but also wafers with organic passivation or individual chips that are unable to be supported without adhesive. The proposed method may therefore in particular enable nanoporous bumps to be produced on such substrates. For this purpose, as described above, a nanoporous bump may first be produced on a first substrate, in particular one that may withstand the de-alloying process, and the bump may subsequently be transferred by means of compression bonding to the second substrate, which in particular comprises a material that may be more sensitive to an etching solution used for de-alloying than the first substrate material. The nanoporous bump may also be transferred from the first substrate to the second substrate because the second substrate is in a format that does not allow structuring of the bump, e.g., because it is present as a chip, wafer portion or as a rectangular substrate.

In an embodiment, a growth starter layer of the nanoporous bump remains at least partially adhered to the first substrate. A growth starter layer may be a first layer that is applied to the first substrate during electrodeposition of the metal alloy by applying a voltage. The bump produced on the second substrate may be correspondingly smaller than the bump that was initially applied to the first substrate.

When mechanically separating the first substrate from the second substrate, it is necessary that the adhesive strength of the bump on the second substrate is higher than on the first substrate. This may be achieved in particular by achieving sufficient strength to the second substrate during compression bonding, while the adhesion to the first substrate remains lower due to the higher porosity.

In an embodiment, the first substrate may be mechanically separated from the second substrate, in particular separated from the second substrate by tensile stress or by shearing. For example, the first and/or second substrate may be suctioned by a vacuum tool and lifted off vertically. Alternatively, the first and/or second substrate may be sheared laterally by a tool. The tensile or shear strength may typically be at least 3 and/or at least 4 and/or at least 5 MPa. The tensile or shear strength may typically be a maximum of 20 and/or a maximum of 18 and/or a maximum of 15 MPa. The bump may have, on its underside, a first bump base area, which is connected to the first substrate. The bump may have, on its upper side, a second bump base area, which is connected to the second substrate. The first bump base area may have the same size and/or shape as the second bump base area. The first and/or second bump base area may be referred to as the bump area.

The first substrate may have a first substrate base area facing the second substrate. The bump may be arranged at its first bump base area on the first substrate base area, in particular before the first and second substrates are separated. The second substrate may have a second substrate base area that faces the first substrate. The bump may be arranged at its second bump base area on the second substrate base area, in particular before the first and second substrates are separated. The first substrate base area may have the same size and/or shape as the second substrate base area. However, the first substrate base area may also be a multiple of the second substrate base area, which may be used, for example, to bond individual chips to the first substrate several times and to transfer the bumps with the separation. Conversely, it may also be advantageous if the second substrate base area is many times larger than the first substrate base area. For example, the second substrate may be a printed circuit board or a flexible cable onto which nanoporous bumps are to be transferred only locally. Here, the first substrate may be divided into individual elements that are locally compression-bonded to the second substrate and the bumps may be transferred to the printed circuit board or the flexible cable by being separated.

The ratio between bump area and substrate area may influence the type and method of separation. In particular, if the bump area is significantly less than 1% of the first and/or second substrate area, a vacuum for suctioning the first and/or second substrate may be formed in such a way that separation may be achieved under tension. It may be advantageous to separate the substrates by shearing, particularly for bump areas greater than 1% of the first and/or second substrate area, since the maximum suction force of a vacuum may be too low to separate the substrates by tension.

The first and/or second bump base area may have a length of at least 0.2 μm and/or at least 2 μm and/or at least 10 μm and/or a length of at most 40 μm and/or a length of at most 100 μm and/or a length of at most 10 mm. Accordingly, the length of the bump area, for example in the case of bumps for micro-LEDs, may be in the lower range, in particular at 1 μm or less, and may extend up to approximately 10 mm, wherein this applies, for example, to die-bond surfaces in power electronics.

The first and/or second and/or third substrate base area may have a length of at least 2 μm and/or at least 200 μm and/or at least 1 mm and/or a length of at most 100 μm and/or of at most 5 mm and/or of at most 800 mm. The second or third substrates may be micro-LEDs, for example, so that the length is less than 10 μm, or they may be printed circuit board panels, for example, so that the length is up to 800 mm.

In an embodiment, compression rates of at most 3% and/or at most 5% and/or at most 25%, and/or compression rates of at least 1% and/or at least 2% and/or at least 3% may be set during the compression bonding to the second substrate. This may be particularly advantageous in order to achieve good adhesion of the bumps on the bond side on the one hand, but not to compress the nanoporous structure too much on the other hand.

In an embodiment, a third substrate may be provided, in particular with a bond pad. The nanoporous bump may be bonded to the third substrate, in particular to the bond pad of the third substrate, on a side facing away from the second substrate, in particular by means of compression bonding. The bonding of the nanoporous bump to the third substrate, in particular to the bond pad of the third substrate, is typically carried out after the separation from the first substrate. The side of the nanoporous bump facing away from the second substrate is typically a separation surface, i.e., the top side of the nanoporous bump, which is formed after separation of the first and second substrates in the bump. The bond pad usually comprises several metal layers that serve as an adhesive layer, diffusion barrier, oxidation protection or as a ductile contact metal. A contact metal compatible with gold and an oxidation-resistant noble metal, such as gold and/or platinum and/or silver, may be located directly on the surface. Typical layer sequences are Ti/Pt/Au or Ni/Pd/Au or TiW/Au or Ti/Ag.

In an embodiment, compression rates of at most 75% and/or at most 70% and/or at most 50%, and/or compression rates of at least 5% and/or at least 15% and/or at least 30% may be set during the compression bonding to the third substrate. In particular, a sum of the set compression rates during the compression bonding to the second and third substrates may result in 100% and/or at least 60% and/or at least 25%. During compression bonding, in particular thermo-compression bonding of the second substrate, for example in the form of a product chip onto the third substrate, for example a product substrate, the remaining compression capacity may still be used up to around 70%. At this compression rate, the pores may have almost disappeared. Compression rates of approximately 30-50% may be aimed for.

In an embodiment, the compression bonding of the nanoporous bump to the second substrate and/or the compression bonding of the nanoporous bump to the third substrate may be thermo-compression bonding. In thermo-compression bonding, temperatures of at least 20° C. and/or at least 150° C. and/or at least 200° C. and/or at least 250° C. and/or at most 300° C. and/or at most 350° C. and/or at most 450° C. may be used. For thermo-compression bonding, temperatures and forces may be selected in such a way that good adhesion of the bumps on the bond side is achieved on the one hand, but the nanoporous structure is not compressed too much on the other hand.

Thermal treatment may allow the material, which has solidified due to compression during transfer, to recover and the bonding pressures required for bonding to the third substrate, for example flip-chip bonding of the product chip to the product substrate, may be further reduced.

The compression bonding may be flip-chip compression bonding. This may apply in particular when bonding on the active side of a semiconductor with its bond pads.

In an embodiment, the metal alloy may first have a less noble and then a more noble alloy composition when a voltage is applied during the electrodeposition. In particular, the bump may have an alloy composition such that during de-alloying a bump is formed which has a first layer and a second layer, wherein the first layer has a higher pore density than the second layer. The alloy composition may be essential for the degree of porosity of the bump after de-alloying. The alloy composition may be influenced, for example, by the current density and/or by bath movement and/or by changing the electrolyte composition.

When electrodepositing the metal alloy by applying a voltage, the current density may be kept low at the start of the deposition and increased during the course of the deposition. In this way, a less noble and then a more noble alloy composition may first be created.

For example, the current density may be successively and/or continuously increased in the course of the deposition. The pore density in the bump may gradually increase and/or decrease, in particular decrease in a growth direction of the bump.

In an embodiment, a coarsening of the pores on the growth side of the first substrate and a reduction in the adhesive force may be achieved after de-alloying by temperature aging. The nanoporous structure may be directly adjacent to a planar starter layer. During the annealing process, there may be a net diffusion current due to the gradient in the curvature of the porous structure near the planar transition, which leads to a reduction in adhesion. This may make it easier to separate the first substrate from the second substrate. In particular, the separation may be facilitated by the fact that the adhesive force is reduced in the region of the coarser pores. The separation surface may be defined in essence in the bump.

The adhesion of the nanoporous gold may therefore be lower than the cohesion of the material on the growth starting side in order to promote separation. The deposition conditions may be adjusted in such a way that a starter layer with a higher silver content is obtained, which leads to a higher pore density at the interface.

In an embodiment, the alloy may be an Au/Ag alloy and may be de-alloyed such that the resulting nanoporous bump comprises nanoporous gold.

When depositing the Ag/Au alloy at the beginning, more silver may be deposited than gold. For example, a separation region may be defined in the bump.

In an embodiment, the connection metallization of the second substrate may be made of a noble metal, such as gold, silver, platinum or palladium, or may comprise the noble metal, such as gold, silver, platinum or palladium. The low oxidation tendency of the noble metals ensures a good bond connection with sufficient electrical conductivity. The noble metal may therefore form the surface of the bond pad in particular, but there may also be other metals underneath.

In an embodiment, the metal alloy may be chemically de-alloyed in the step “de-alloying the metal alloy to produce a nanoporous bump”. Alternatively or additionally, the principle of electrodeposition in a suitable electrolyte may be reversed electrolytically.

The first substrate may be a silicon or glass wafer. The second and/or third substrate may be a printed circuit board or a product chip or a product wafer. The second substrate may be bonded to the first substrate using compression bonding to transfer the bumps. It may also prove advantageous to divide the first substrate into individual chips and to connect these chips formed from the first substrate to the second substrate by means of compression bonding and to transfer the bumps.

The present disclosure further relates to a component, in particular a semiconductor component, comprising a substrate with a nanoporous bump arranged thereon. For example, the substrate may be configured in such a way that it has an organic passivation layer. In particular, the substrate may have a material that would be damaged by de-alloying, especially chemical de-alloying, in particular by means of an etching solution. In particular, the substrate may comprise organic material and/or have an organic passivation layer. The proposed method may thus make it possible to produce a component that has a nanoporous bump arranged on a material that would not withstand a conventional production process for such a bump.

On a side of the component facing the bump, the substrate may comprise at least one organic layer. This may be at least partially exposed. In particular, the organic layer may be an adhesive layer, an optical layer, especially in the form of a filter or a waveguide, an encapsulation, a solder stop and/or a dielectric layer.

On a side of the component facing the bump, the substrate may consist of or comprise a compound semiconductor, in particular a III/V semiconductor or a II/VI semiconductor. The substrate may be at least partially exposed.

On a side of the component facing the bump, the substrate may consist of or comprise a III/V semiconductor, in particular GaAs or GaN or GaSb or InP or InGaN. The substrate may be at least partially exposed.

On a side of the component facing the bump, the substrate may consist of or comprise a II/VI semiconductor, in particular tellurides (CdTe, ZnTe, HgTe) or selenides (ZnSe, CdSe) or sulfides (ZnS, CdS) or mixtures of the elements. The substrate may be at least partially exposed.

On a side of the component facing the bump, the substrate comprising organic material may be at least partially exposed. Additionally or alternatively, an organic passivation layer may be at least partially exposed. Other at least partially exposed organic layers may be an adhesive layer, an optical layer (e.g., a filter or a waveguide), an encapsulation, a solder stop or a dielectric layer.

In particular, the component substrate may be the second substrate described above. The component according to the present disclosure may be produced by a method described above.

### BRIEF DESCRIPTION OF THE DRAWINGS

The present disclosure is explained in greater detail below with reference to exemplary, non-limiting embodiments. In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document. In the drawings:

FIGS. 1 a-k illustrate examples of a cross-sectional view and schematic representations of individual method steps of an exemplary production process of a substrate with nanoporous bump.

### DETAILED DESCRIPTION

Recurring features are provided with the same reference signs.

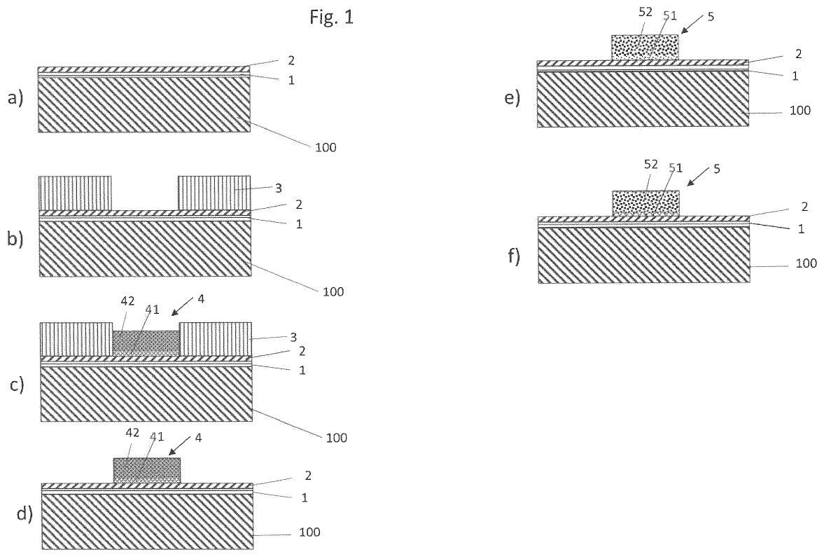

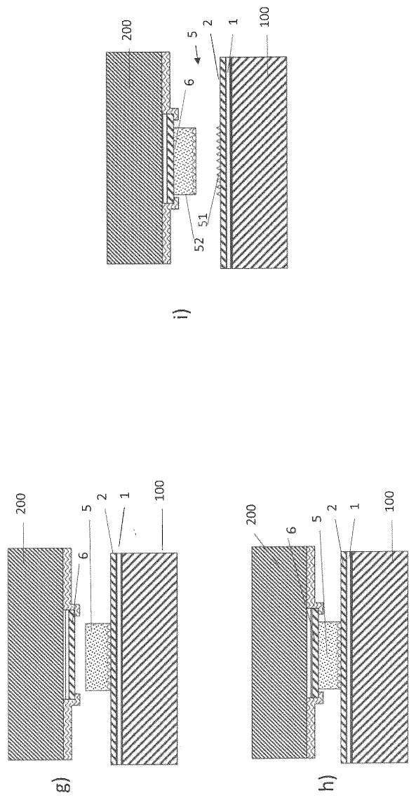

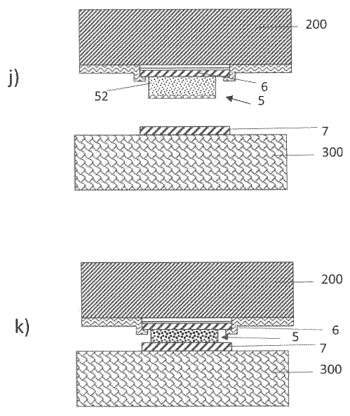

First, as shown in FIG. 1a, a plating base 1 is applied to the substrate 100 in the form of a layer to reinforce adhesion, for example made of titanium, titanium/tungsten or chromium, and a starter layer 2 made of gold, nickel, copper or platinum is applied on top, wherein this may be done by sputtering. Then, as shown in FIG. 1b, a photosensitive coating 3 is applied to the starter layer 2, for example by spinning. The coating 3 is exposed with a bump mask and developed so that the coating 3 is present in some regions on the starter layer 2 as shown in FIG. 1b.

According to FIG. 1c, a gold/silver alloy 4 is electrodeposited, wherein the alloy-forming metal elements are initially present in an electrolyte and electrochemical deposition from the electrolyte takes place by applying a current. The current may be a measure of the reduction of the anions to metal. The composition of the gold/silver deposition ranges from 15% to 40% gold and 85% to 60% silver. As an intermediate step according to FIG. 1c, there is therefore a gold/silver layer 4 on the starter layer 2. A layer 41 with a higher silver content is deposited first, followed by a layer 42 containing less silver than layer 41.

The coating 3 is removed, as shown in FIG. 1d. Then, between FIG. 1d and the illustration according to FIG. 1e, in which a nanoporous bump 5 is shown, the silver is released from the layer 41 to the porous layer 51 and from the layer 42 to the porous layer 52, wherein this selective release or discarding may be carried out in different ways. One possibility, especially if electrochemical deposition is used, is the electrolytic reversal of the principle of electrodeposition in a suitable electrolyte, in which a voltage is applied to the electrodes, thus dissolving out the silver but retaining the gold. Another option is to selectively remove the silver by etching it without external current, e.g., in solutions containing nitric acid. The layer 51 has a lower density than the layer 52 and is more porous than the layer 52.

During the process of releasing the silver, a surface reaction takes place in the Ag/Au layer 5, in which silver dissolves as an ion from the uppermost metal layer. The remaining Au atoms accumulate on the surface to form islands and selectively protect the surface from further dissolution. Silver is then extracted from the next metal layer, which is not covered by a gold island. By reattaching the mobile Au atoms from the layer, a 3D sponge layer with nanoscale pores slowly grows, as shown in FIG. 1e. The sponge-like nanoporous layer is denoted 5. FIG. 1 f shows a thermally aged sample. For this purpose, the first substrate with the nanoporous sponge is annealed at higher temperatures, e.g., at 200° C. or 250° C. for a longer time, e.g., for 30 minutes or for several hours.

In a subsequent step, a second substrate 200, for example in the form of a product chip having a bond pad 6 made of gold, is aligned with respect to the first substrate 100 having the nanoporous bump 5 (as shown in FIG. 1g) and bonded thereto via compression bonding (as shown in FIG. 1h). The bump 5 may be at least partially compressed here, as is evident in FIG. 1h.

In a further step, the first substrate 100 is separated from the second substrate 200, for example—as shown in FIG. 1i—by tensile loading, for example by means of a vacuum. The bump 5 is separated in the region between the layers 51 and 52, in particular so that parts of the bump 5, in particular the layer 51, adhere to the first substrate 100 and parts of the bump 5, in particular the layer 52, adhere to the second substrate 200. The bump 5 is therefore substantially transferred to the second substrate 200.

As shown in FIG. 1j, the second substrate 200 may be aligned with the transferred bump 5 relative to a third substrate 300, which has a bond pad 7 on its surface facing the second substrate 200. The bump 5 may be connected to the bond pad 7 of the third substrate 300 via compression bonding. The bump 5 may be at least partially compressed here, as is evident in FIG. 1k.

The present approach is explained in greater detail below with reference to two exemplary embodiments. For the features that have already been explained in greater detail in relation to the figures described above, the associated reference signs are repeated.

### Exemplary Embodiment 1

Product chips made of GaAs are only available as individual chips and are to be bonded to a printed circuit board. The bumps 5 are to be transferred to the GaAs chip in the example. Therefore, nanoporous bumps 5 are produced on a wafer as the first substrate 100. For this purpose, the pad arrangement of the GaAs chip is mirrored in a mask and produced in a grid for a large number of chips. A bare wafer (e.g., a silicon monitor wafer) is used to produce the bumps 5 from nanoporous gold. After sputtering and lithography, an AgAu alloy 4 is deposited. For example, the alloy is initially deposited at a lower current density, which is then increased to the target value. After stripping the resist, either the whole wafer may be reused or the wafer may be sawn into portions or even into chip size for a single product chip.

Adjustment marks for bonding the chips may also be included in the mask. If the adjustment mark on the product chip is under a passivation, no nanoporous gold is transferred to the adjustment mark on the product chip during the transfer.

The product chip 200 as the second substrate, for example GaAs, is adjusted via a pad arrangement and bonded by means of flip-chip thermo-compression. Typical parameters are 70 to 200° C. and the bonding pressures are 10 to 200 MPa. The bonding pressure is calculated by dividing the bonding force by the area of the bumps. Annealing at 200 to 300° C. for a few minutes may increase the adhesive force to the product chip 200 and further reduce the adhesive force of the bumps 5 on the first substrate 100.

After the product chip is bonded as second substrate 200 to the first substrate 100, it is mechanically removed again from the first substrate 100. It is either suctioned with a vacuum tool and lifted off vertically or sheared sideways with a tool. The tensile or shear strength is typically around 5-15 MPa. If the bump area is significantly less than 1% of the chip area, the vacuum for suctioning the chip may be formed in such a way that separation is achieved under tension. For bump areas greater than 1%, the maximum suction force may not be sufficient to separate the chip by tension, and the separation takes place by shearing the first substrate 100 in relation to the second substrate 200. In both cases, the bumps 5 are transferred to the product chip in the form of the second substrate. As a final step, the product chip based on the GaAs is flip-chip bonded to the printed circuit board using thermo-compression. The contact pads on the printed circuit board are embodied with currentless nickel/palladium/gold (ENIPIG) for this purpose.

### Exemplary Embodiment 2

The bumping of printed circuit boards with just a few bumps per substrate is uneconomical. Sputtering processes on large-format printed circuit boards are unusual for cost reasons and the printed circuit board would be damaged by the de-alloying process. In this example, the bumps are to be transferred to the printed circuit board using a transfer chip. Therefore, nanoporous bumps 5 are produced on a wafer as the first substrate 100. For this purpose, the pad arrangement is mirrored by the printed circuit board connections in a mask and produced in a grid for a large number of transfer chips. A bare wafer (e.g., a silicon monitor wafer) is used to produce the bumps 5 from nanoporous gold. After sputtering and lithography, the AgAu alloy 4 is deposited. For example, the alloy is initially deposited at a lower current density, which is then increased to the target value. After stripping the resist, the wafer is sawn into transfer chips, which contain the connections for chip assembly on the printed circuit board.

Adjustment marks for bonding the transfer chips to the printed circuit board may also be included in the mask.

The transfer chip in the form of the substrate 200 is adjusted via a pad arrangement of the printed circuit board and bonded by means of flip-chip thermo-compression. Typical parameters are 70 to 200° C. and bonding pressures of 10 to 200 MPa. For printed circuit boards, a temperature below the glass transition should be selected, which may be between 15° and 280° C. depending on the printed circuit board material. The bonding pressure is calculated by dividing the bonding force by the area of the bumps 5. Annealing at 200 to 300° C. (or maximum temperature of the printed circuit board, typically below the decomposition temperature of the material) for a few minutes may increase the adhesive force to the printed circuit board and further reduce the adhesive force of the bumps on the first substrate.

After the transfer chip has been bonded to the printed circuit board in the form of the second substrate 200, the transfer chip in the form of the first substrate is mechanically removed again. It is either suctioned with a vacuum tool and lifted off vertically or sheared sideways with a tool. The tensile or shear strength is typically around 5-15 MPa. If the bump area is significantly less than 1% of the chip area, the vacuum for suctioning the chip may be formed in such a way that separation is achieved under tension. In the case of bump areas greater than 1%, the maximum suction force may not be sufficient to separate the chip by tension and the separation takes place by shearing the first substrate in relation to the second substrate. In both cases, the bumps 5 are transferred to the printed circuit board, i.e., the second substrate 200.

The present disclosure may thus have the advantage that no product wafers or substrates are required for bumping with nanoporous gold, nor do they have to meet the process requirements (e.g. compatibility with the de-alloying process).

The method described above may be used in particular for bumping individual chips of various semiconductor materials, for example silicon, InP, GaAs, GaN, SiC, CdZnTe, for photonics, sensors, amplifiers, memories, processors and/or for bumping substrates, for example glass substrates, ceramic substrates, flexible and rigid organic printed circuit boards made of or comprising FR-4, polyimide and/or HF printed circuit boards and/or bumping flexible cable ends as electrical connectors.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the embodiments should be determined with reference to the appended claims, along with the full scope of equivalents to which such claims are entitled.

What is claimed is:

1. A method for producing a substrate having a nanoporous bump, the method comprising:
providing a first substrate and a second substrate, wherein the second substrate has a connection metallization;
structured electrodepositing of a metal alloy by applying a voltage;
de-alloying the metal alloy to produce a nanoporous bump; and
compression bonding the nanoporous bump to the second substrate, wherein a bump top side facing away from the first substrate is welded to the connection metallization of the second substrate, wherein after compression bonding, the second substrate is separated from the first substrate, wherein the nanoporous bump is at least partially transferred from the first substrate to the second substrate.

2. The method according to claim 1, wherein a growth starter layer of the nanoporous bump remains at least partially adhered to the first substrate.

3. The method according to claim 1, wherein the first substrate is separated from the second substrate by at least one of tensile stress or by shearing.

4. The method according to claim 1, wherein a compression rate of at least one of: i) at most at most 25%, or ii) at least 1% are set during the compression bonding to the second substrate.

5. The method according to claim 1, wherein a third substrate is provided with a bonding pad and wherein the nanoporous bump is bonded to the bonding pad of the third substrate on a side facing away from the second substrate.

6. The method according to claim 5, wherein a compression rates of at least one of: i) at most 75% or ii) at least 5% are set during the compression bonding to the third substrate.

7. The method according to claim 1, wherein the structured electrodepositing is achieved by applying a plating base to the first substrate, applying a photosensitive coating to the plating base, exposing with a bump mask and developing the photosensitive coating, and wherein the photosensitive coating is removed after the structured electrodepositing.

8. The method according to claim 1, wherein the metal alloy first has a less noble and then a more noble alloy composition when a voltage is applied during the electrodeposition of the metal alloy so that, during the de-alloying, a bump is produced having a first layer and a second layer, wherein the first layer has a higher pore density than the second layer.

9. The method according to claim 8, wherein when electrodepositing the metal alloy by applying a voltage, a current density is kept low at the start of the structured electrodepositing and increased during the course of the structured electrodepositing, so that firstly a less noble and subsequently a more noble alloy composition is produced.

10. The method according to claim 9, wherein a pore density in the bump at least one of gradually increases or decreases, and wherein, when the pore density decreases, the pore density decreases in a growth direction of the bump.

11. The method according to claim 7, wherein a coarsening of pores on a growth side of the first substrate and a reduction in an adhesive force are achieved after de-alloying by temperature aging.

12. The method according to claim 1, wherein the metal alloy is an Au/Ag alloy and is de-alloyed such that the nanoporous bump resulting from the de-alloying comprises nanoporous gold.

13. The method according to claim 12, wherein when depositing the Au/Ag alloy at the beginning, more silver is deposited than gold.

14. The method according to claim 13, wherein the connection metallization of the second substrate comprises a noble metal, and wherein the noble metal includes at least one of gold, silver, platinum, or palladium.

15. The method according to claim 1, wherein the metal alloy is chemically de-alloyed when de-alloying the metal alloy to produce a nanoporous bump.

16. The method according to claim 1, wherein the second substrate is a printed circuit board, a product chip, or a product wafer.

17. A component comprising:
a substrate with a nanoporous bump arranged thereon, wherein at least one of: i) the substrate comprises organic material, or ii) has an organic passivation layer.

18. The component according to claim 17, wherein on a side of the component facing the nanoporous bump, at least one of: i) the substrate comprising organic material is at least partially exposed, or ii) the organic passivation layer is at least partially exposed.

19. The component according to claim 17, wherein on a side of the component facing the nanoporous bump, the substrate comprises at least one organic layer, wherein the at least one organic layer is at least partially exposed, and wherein the at least one organic layer is at least one of an adhesive layer, an optical layer, an encapsulation, a solder stop, or a dielectric layer.

20. The component according to claim 17, wherein on a side of the component facing the nanoporous bump, the substrate comprises a compound semiconductor, wherein the compound semiconductor is a III/V semiconductor or a II/VI semiconductor, and wherein the substrate is at least partially exposed.

21. The component according to claim 17, wherein on a side of the component facing the nanoporous bump, the substrate comprises a III/V semiconductor, wherein the III/V semiconductor includes GaAs, GaN, GaSb, InP, or InGaN, and wherein the substrate is at least partially exposed.

22. The component according to claim 17, wherein on a side of the component facing the nanoporous bump, the substrate comprises a II/VI semiconductor, wherein the II/VI semiconductor includes a telluride, a selenide, a sulfide, or a mixture thereof, and wherein the substrate is at least partially exposed.
